(19) United States
(12) Patent Application Publication
(10) Pub. No.: US 2026/0052725 A1
(43) Pub. Date: Feb. 19, 2026

(54) SHALLOW TRENCH ISOLATION STRUCTURES AND TECHNIQUES

(71) Applicant: Taiwan Semiconductor Manufacturing Company, Ltd., Hsinchu (TW)

(72) Inventors: Chung-Lei Chen, Hsinchu (TW); Yen-Liang Lin, Tainan City (TW); Ru-Shang Hsiao, Jhubei City (TW)

(73) Assignee: Taiwan Semiconductor Manufacturing Company, Ltd., Hsinchu (TW)

(21) Appl. No.: 18/802,258

(22) Filed: Aug. 13, 2024

(51) Int. Cl. H01L 29/78; H01L 21/762; H01L 21/768; H01L 29/66

(52) U.S. Cl. CPC H10D 30/65; H01L 21/76232; H01L 21/76816; H01L 21/76819; H10D 30/0287

(57) ABSTRACT

A semiconductor structure is disclosed that includes: a source feature and a drain feature disposed in a substrate; a gate structure disposed above the substrate and between the source feature and the drain feature; and a first ladder shallow trench isolation (STI) feature disposed in the substrate at least partially under the gate structure in a channel region between the source feature and the drain feature, the first ladder STI feature including a plurality of sections of different depths including a first depth section and a second depth section.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional diagram of an example semiconductor device that includes a laterally-diffused metal-oxide semiconductor device, according to some embodiments.

FIG. 2A is a schematic cross-sectional view of an example LDMOS device that includes a 1L ladder STI with 2 depths under an LDMOS gate structure, according to some embodiments.

FIG. 2B is a schematic cross-sectional view of an example LDMOS device that includes a 2L ladder STI with 3 depths under an LDMOS gate structure, according to some embodiments.

FIG. 3A is a schematic cross-sectional view of an example LDMOS device, according to some embodiments.

FIG. 3B is a schematic cross-sectional view of another example LDMOS device, according to some embodiments.

FIG. 3C is a schematic cross-sectional view of another example LDMOS device, according to some embodiments.

FIG. 4A is a schematic cross-sectional view of an example substrate with a 1L STI feature formed therein, according to some embodiments.

FIG. 4B is a schematic cross-sectional view of an example 1L STI feature, according to some embodiments.

FIG. 5A illustrates an example substrate with a 1L ladder STI structure having a higher depth region and a lower depth region, according to some embodiments.

FIG. 5B illustrates another example substrate with a 1L ladder STI structure having a higher depth region and lower depth regions, according to some embodiments.

FIG. 5C illustrates another example substrate with a 1L ladder STI structure having a higher depth region and a lower depth region, according to some embodiments.

FIG. 5D illustrates another example substrate with an xL ladder STI structure having a plurality of regions of different depth, according to some embodiments s.

FIG. 5E illustrates a top view of a substrate with the 1L ladder STI structure having a lower depth region on the left side and a higher depth region on the right side of the 1L ladder STI structure, according to some embodiments.

FIG. 5F illustrates a top view of a substrate with the 1L ladder STI structure having lower depth regions on both the left side and the right side of a 1L ladder STI structure and a higher depth region in the center of the 1L ladder STI structure, according to some embodiments.

FIG. 5G illustrates a top view of a substrate with the 1L ladder STI structure having a lower depth STI region on the right side and a higher depth STI region on the left side of the 1L ladder STI structure, according to some embodiments.

FIG. 5H illustrates a top view of a substrate with an xL ladder STI structure having a lower depth region on the left side and a higher depth region on the right side of the xL ladder STI structure with intermediate depth regions in depth order disposed between, according to some embodiments.

FIG. 6A is a schematic cross-sectional view of an example device, according to some embodiments.

FIG. 6B is a schematic cross-sectional view of another example device, according to some embodiments.

FIG. 7 is a flow diagram of an example method for fabricating a semiconductor device having a ladder STI feature, according to some embodiments.

FIGS. 8A-8I, are cross-sectional views of a semiconductor device at various stages of its fabrication process, according to some embodiments.

FIG. 9 is a flow diagram of another example method for fabricating a semiconductor device having a ladder STI feature, according to some embodiments.

FIGS. 10A-10E are schematic cross-sectional views of example LDMOS devices that include a ladder STI feature, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°less than or equal to ±4°, less than or equal to ±3°, less than or equal to ±2°, less than or equal to ±1°, less than or equal to ±0.5°, less than or equal to ±0.1°, or less than or equal to ±0.05°.

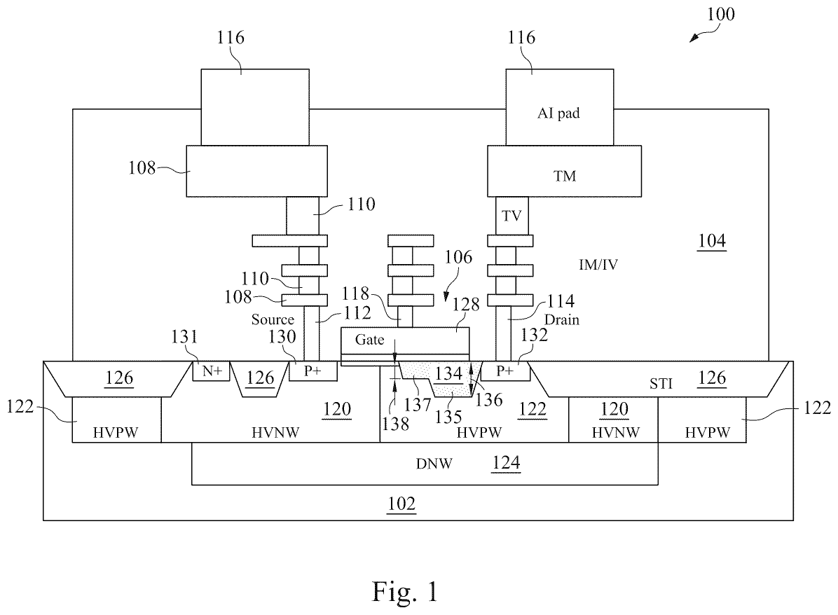

FIG. 1 is a schematic cross-sectional view of an example semiconductor device 100 that includes a laterally-diffused metal-oxide semiconductor device (LDMOS device 106), according to some embodiments. The example semiconductor device 100 includes a substrate 102 and an interconnect structure 104 that overlies the substrate 102. The substrate 102 includes a plurality of high voltage n-well structures (HVNW 120), a plurality of high voltage p-well structures (HVPW 122), and a deep n-well structure (DNW 124). The substrate 102 further includes a shallow trench isolation feature (STI 126) for isolating various components. An LDMOS device 106 is formed in and on the substrate 102 in this example. The interconnect structure 104 includes metal lines 108 and VIAs 110 that connect a source terminal 112 and a drain terminal 114 of the LDMOS device 106 to device pads 116 of the semiconductor device 100, and connect a gate terminal 118 of the LDMOS device 106 to other components (not shown) within the semiconductor device 100.

The example LDMOS device 106 is a planar double-diffused MOSFET (metal-oxide-semiconductor field-effect transistor) used in amplifiers, including microwave power amplifiers, RF power amplifiers and audio power amplifiers, among others. The example LDMOS device 106 includes a source feature formed in an HVNW 120, a drain feature formed in an HVPW 122, and a gate structure 128 formed over a channel region in the substrate 102 and between the source feature and the drain feature. The source feature comprises a p+ (positively charged) doped region 130 in the HVNW 120 and the drain feature comprises a p+ doped region 132 in the HVPW 122. The doped region of the source feature is of the same polarity type as the doped region of the drain feature. In this example, the polarity type is a positive polarity. In other embodiments, the polarity may be a negative polarity. The LDMOS device 106 further includes a n+ (negatively charged) doped region 131 in the HVNW 120 separated from the p+ doped region 130 by STI 126.

The LDMOS device 106 includes a STI feature 134 disposed in the substrate 102 at least partially under the gate structure 128 in the channel region to prevent HV (high voltage) breakdown. The STI feature 134 is a ladder STI feature having a plurality of sections with different depths, a first depth section 135 having a first depth 136 and a second depth section 137 having a second depth 138 in this example. The plurality of depths allow the STI feature 134 to help prevent HV breakdown while improving the speed of the LDMOS device 106. The higher depth portion of the STI feature 134 (first depth section 135 with first depth 136) can help with HV breakdown prevention while the lower depth portion of the STI feature 134 (second depth section 137 with second depth 138) can help improve the speed of the LDMOS device 106. The channel region has a drain side that spans between an area in the substrate 102 that is below a middle position of the gate structure 128 in a lateral direction and p+ doped region 132, and the STI feature 134 is disposed on the drain side of the channel region.

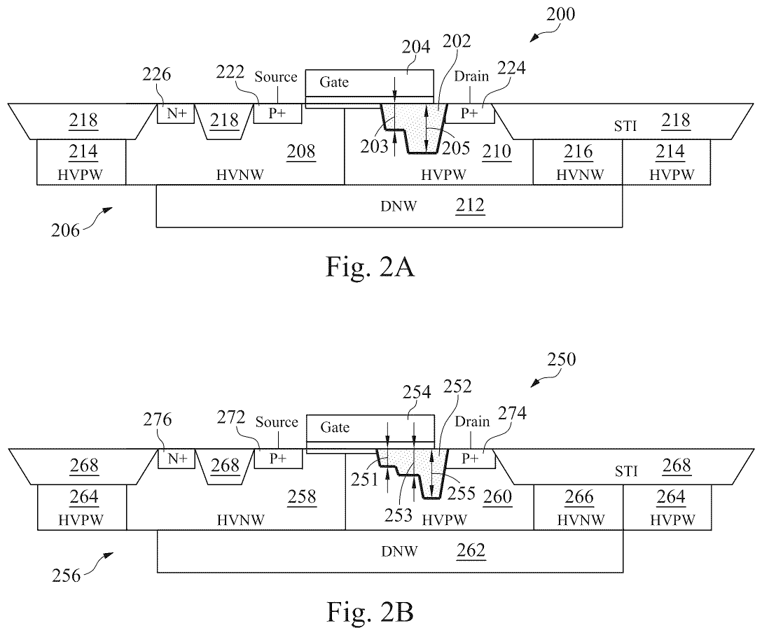

FIGS. 2A and 2B are schematic cross-sectional views of example LDMOS devices that include ladder STI under a LDMOS gate structure to help prevent HV breakdown while improving the speed of the LDMOS device. FIG. 2A is a schematic cross-sectional view of an example LDMOS device 200 that includes a 1L ladder STI feature 202 with 2 depths (depth 203 and depth 205) under an LDMOS gate structure 204. FIG. 2B is a schematic cross-sectional view of an example LDMOS device 250 that includes a 2L ladder STI feature 252 with 3 depths (depth 251, depth 253, and depth 255) under an LDMOS gate structure 254.

The example LDMOS device 200 includes a substrate 206 with a HVNW 208, a HVPW 210, and a DNW 212. In various embodiments, the LDMOS device 200 further includes HVPW 214, HVNW 216, STI 218. The example LDMOS device 200 includes a source feature formed in an HVNW 208, a drain feature formed in an HVPW 210, and a gate structure 204 formed over a channel region in the substrate 206 and between the source feature and the drain feature. The channel region has a drain side that spans between an area in the substrate 206 that is below a middle position of the gate structure 204 in a lateral direction and p+doped region 224, and the 1L ladder STI feature 202 is disposed on the drain side of the channel region.

The source feature comprises a p+ doped region 222 in the HVNW 208 and the drain feature comprises a p+ doped region 224 in the HVPW 210. The doped region of the source feature is of the same polarity type as the doped region of the drain feature. In this example, the polarity type is a positive polarity. In other embodiments, the polarity may be a negative polarity. The LDMOS device 200 further includes a n+ doped region 226 in the HVNW 208 separated from the p+ doped region 222 by STI 218.

The example LDMOS device 250 includes a substrate 256 with a HVNW 258, a HVPW 260, and a DNW 262. In various embodiments, the LDMOS device 250 further includes HVPW 264, HVNW 266, STI 268. The example LDMOS device 250 includes a source feature formed in an HVNW 258, a drain feature formed in an HVPW 260, and a gate structure 254 formed over a channel region in the substrate 256 and between the source feature and the drain feature. The channel region has a drain side that spans between an area in the substrate 256 that is below a middle position of the gate structure 254 in a lateral direction and p+ doped region 274, and the 2L ladder STI feature 252 is disposed on the drain side of the channel region.

The source feature comprises a p+ doped region 272 in the HVNW 208 and the drain feature comprises a p+ doped region 274 in the HVPW 260. The doped region of the source feature is of the same polarity type as the doped region of the drain feature. In this example, the polarity type is a positive polarity. In other embodiments, the polarity may be a negative polarity. The LDMOS device 250 further includes a n+ doped region 276 in the HVNW 258 separated from the P+ doped region 272 by STI 268.

The example of FIG. 2A illustrates a 1L ladder STI structure. The example of FIG. 2B illustrates a 2L ladder STI structure. In other embodiments, an xL ladder STI structure with x+1 different depths may be formed.

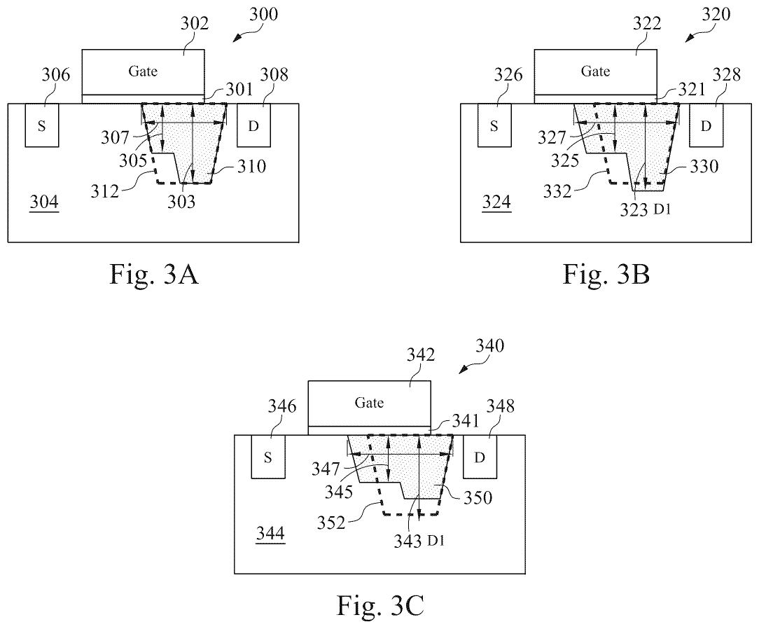

FIGS. 3A, 3B, and 3C are schematic cross-sectional views of example LDMOS devices that include ladder STI under a LDMOS gate structure. FIG. 3A is a schematic cross-sectional view of an example LDMOS device 300. The LDMOS device 300 includes a gate structure 302 and gate oxide 301 over a substrate 304, a source feature 306 in the substrate 304, and a drain feature 308 in the substrate 304. The LDMOS device 300 further includes a 1L ladder STI 310 with 2 depths (first depth 303 and second depth 305) and a width 307 in a channel region of the substrate 304 under the gate structure 302 on the drain side of the channel region. Each of the first depth 303 and the second depth 305 extend lower into the substrate 304 than the bottom of the source feature 306 and the bottom of the drain feature 308. In various embodiments, the ratio of the first depth 303 to the second depth 305 is approximately 1.2:1 to approximately 3:1.

A different LDMOS device (not shown) may be formed on the substrate 304 that includes a single depth STI feature (not shown) disposed at least partially under the gate structure of the different LDMOS device in a channel region of the different LDMOS device between a source feature of the different LDMOS device and a drain feature of the different LDMOS device. An outline 312 showing dimensions of the single depth STI feature is shown to illustrate relative dimensions of the 1L ladder STI 310, which can prevent HV breakdown while improving the speed of the LDMOS device 300. The single depth STI feature may have the first depth 303 and the width 307. Speed improvement in the LDMOS device 300 over a LDMOS device with a single depth STI (as illustrated by outline 312) can be achieved with use of the 1L ladder STI 310 because the second depth 305 of the STI 310 can provide a shorter channel path between the source feature 306 and drain feature 308 than a single depth STI of the same first depth 303 and width 307.

FIG. 3B is a schematic cross-sectional view of an example LDMOS device 320. The LDMOS device 320 includes a gate structure 322 and gate oxide 321 over a substrate 324, a source feature 326 in the substrate 324, and a drain feature 328 in the substrate 324. The LDMOS device 320 further includes a 1L ladder STI 330 with 2 depths (first depth 323 and second depth 325) and a width 327 in a channel region of the substrate 324 under the gate structure 322 on the drain side of the channel region. Each of the first depth 323 and the second depth 325 extend lower into the substrate 324 than the bottom of the source feature 326 and the bottom of the drain feature 328. In various embodiments, the ratio of the first depth 323 to the second depth 325 is approximately 1.2:1 to approximately 3:1.

A different LDMOS device (not shown) may be formed on the substrate 324 that includes a single depth STI feature (not shown) disposed at least partially under the gate structure of the different LDMOS device in a channel region of the different LDMOS device between a source feature of the different LDMOS device and a drain feature of the different LDMOS device. An outline 332 of the single depth STI feature is shown to illustrate relative dimensions of the 1L ladder STI 330, which can prevent HV breakdown while improving the speed of the LDMOS device 320. The single depth STI feature may have a depth that is shorter than the first depth 323 and a width that is narrower than the width 327. Greater HV performance in the LDMOS device 320 over a LDMOS device with a single depth STI (as illustrated by outline 332) can be achieved with use of the 1L ladder STI 330. The first depth 323 and the width 327 are increased to provide greater HV performance and the second depth 325 reduces speed loss that might occur due to the increased first depth 323 and width 327. The second depth 325 of the STI 330 can provide a shorter channel path between the source feature 326 and drain feature 328 than a single depth STI of the same first depth 323 and width 327.

FIG. 3C is a schematic cross-sectional view of an example LDMOS device 340. The LDMOS device 340 includes a gate structure 342 and gate oxide 341 over a substrate 344, a source feature 346 in the substrate 344, and a drain feature 348 in the substrate 344. The LDMOS device 340 further includes a 1L ladder STI 350 with 2 depths (first depth 343 and second depth 345) and a width 347 in a channel region of the substrate 344 under the gate structure 342 on the drain side of the channel region. Each of the first depth 343 and the second depth 345 extend lower into the substrate 344 than the bottom of the source feature 346 and the bottom of the drain feature 348. In various embodiments, the ratio of the first depth 343 to the second depth 345 is approximately 1.2:1 to approximately 3:1.

A different LDMOS device (not shown) may be formed on the substrate 344 that includes a single depth STI feature (not shown) disposed at least partially under the gate structure of the different LDMOS device in a channel region of the different LDMOS device between a source feature of the different LDMOS device and a drain feature of the different LDMOS device. An outline 352 showing dimensions of the single depth STI feature is shown to illustrate relative dimensions of the 1L ladder STI 350, which can prevent HV breakdown while improving the speed of the LDMOS device 340. The single depth STI feature may have a depth that is larger than the first depth 343 and a width that is narrower than the width 347. Balanced performance with some HV protection and speed enhancements in the LDMOS device 340 as compared to a LDMOS device with a single depth STI (as illustrated by outline 352) can be achieved with use of the 1L ladder STI 350. The width 347 is increased to provide greater HV performance and the reduction in the first depth and second depth 345 can improve device speed and counteract speed loss due to the increased width 347. The second depth 345 of the STI 350 can provide a shorter channel path between the source feature 346 and drain feature 348 than a single depth STI of the same first depth 343 and width 347.

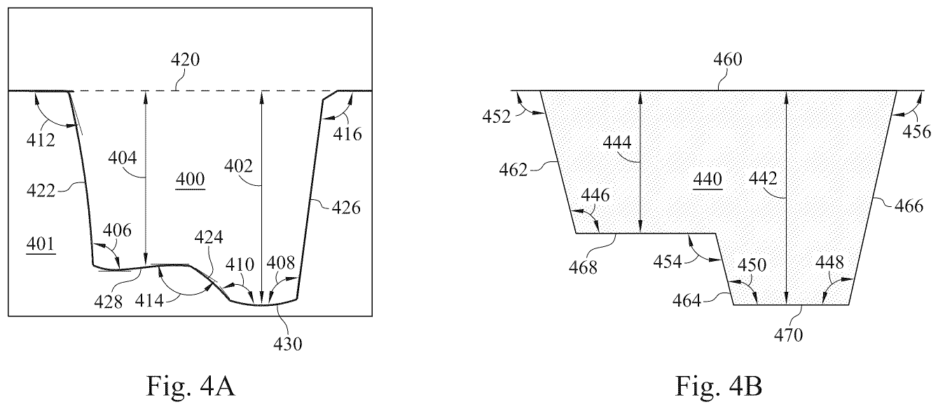

FIG. 4A is a schematic cross-sectional view of an example substrate 401 with a 1L STI feature 400 formed therein. The 1L STI feature 400 has 2 depths, a first depth 402 and second depth 404, wherein the first depth 402 is larger than the second depth 404. The 1L STI feature 400 has a top surface 420, a first wall 422, a second wall 424, a third wall 426, a first bottom surface 428 and a second bottom surface 430. The 1L STI feature has a top surface 420, a first wall 422, a second wall 424, a third wall 426, a first bottom surface 428 and a second bottom surface 430. The top first wall 422 is between the top surface 420 and the first bottom surface 428. The second wall is between the first bottom surface 428 and the second bottom surface 430. The third wall 426 is between the second bottom surface 430 and the top surface 420. The 428 is between the first wall 422 and the second wall 424. The second bottom surface 430 is between the second wall 424 and the third wall 426. In various embodiments, the first wall 422 is a curved first wall, the first bottom surface 428 is a curved first bottom surface, the second wall 424 is a curved second wall, the second bottom surface 430 is a curved bottom surface, and the third wall 426 is a curved third wall.

The 1L STI feature 400 has a plurality of STI inner angles (a first inner angle 406, a second inner angle 408, and a third inner angle 410). The first inner angle 406 is between the first wall 422 and the first bottom surface 428. The second inner angle 408 is between the second bottom surface 430 and the third wall 426. The third inner angle 410 is between the second bottom surface 430 and the second wall 424. The magnitude of the first inner angle 406 is approximately equal to the magnitude of the second inner angle 408. The magnitude of the third inner angle 410 is greater than the magnitude of the first inner angle 406 and the magnitude of the second inner angle 408.

The 1L STI feature 400 has a plurality of STI outer angles (a first outer angle 412, a second outer angle 414, and a third outer angle 416). The first outer angle 412 is between the top surface 420 and the first wall 422. The second outer angle 414 is between the first bottom surface 428 and the second wall 424. The third outer angle 416 is between the top surface 420 and the third wall 426. The magnitude of the first outer angle 412 is approximately equal to the magnitude of the third outer angle 416. The magnitude of the second outer angle 414 is greater than the magnitude of the first outer angle 412 and the magnitude of the third outer angle 416.

FIG. 4B is a schematic cross-sectional view of an example 1L STI feature 440. The 1L STI feature 440 has 2 depths, a first depth 442 and second depth 444, wherein the first depth 442 is larger than the second depth 444. The 1L STI feature 440 has a top surface 460, a first wall 462, a second wall 464, a third wall 466, a first bottom surface 468 and a second bottom surface 470.

The 1L STI feature 440 has a plurality of STI inner angles (a first inner angle 446, a second inner angle 448, and a third inner angle 450). The first inner angle 446 is between the first wall 462 and the first bottom surface 468. The second inner angle 448 is between the second bottom surface 470 and the third wall 466. The third inner angle 450 is between the second bottom surface 470 and the second wall 464. The magnitude of the first inner angle 446 is approximately equal to the magnitude of the second inner angle 448. The magnitude of the third inner angle 450 is greater than the magnitude of the first inner angle 446 and the magnitude of the second inner angle 448.

The 1L STI feature 440 has a plurality of STI outer angles (a first outer angle 452, a second outer angle 454, and a third outer angle 456). The first outer angle 452 is between the top surface 460 and the first wall 462. The second outer angle 454 is between the first bottom surface 468 and the second wall 464. The third outer angle 456 is between the top surface 460 and the third wall 466. The magnitude of the first outer angle 452 is approximately equal to the magnitude of the third outer angle 456. The magnitude of the second outer angle 454 is greater than the magnitude of the first outer angle 452 and the magnitude of the third outer angle 456.

In various embodiments, the difference between the first depth 442 and the second depth 444 can range from above 0 Angstroms (Å) to up to approximately 3000 Å. In various embodiments, the ratio of first depth 442 to the second depth 444 is approximately 1.2:1 to approximately 3:1. In various embodiments, each of the first inner angle 446, second inner angle 448, third inner angle 450, first outer angle 452, second outer angle 454, and third outer angle 456 has a magnitude greater than (>) 90°. In various embodiments, each of the first inner angle 446, second inner angle 448, third inner angle 450, first outer angle 452, second outer angle 454, and third outer angle 456 has a magnitude less than (<) 180°.

In various embodiments, traces of a doped element used for forming the portion (or portions) of the STI feature with the greater depth may be detected in a substrate near the deep trench region with an element concentration of approximately 1E+17 to 1E+18. In various embodiments, n-type material such as Arsenic/Phosphorus/Stibium may be used for forming the portion (or portions) of the STI feature with the greater depth in a substrate.

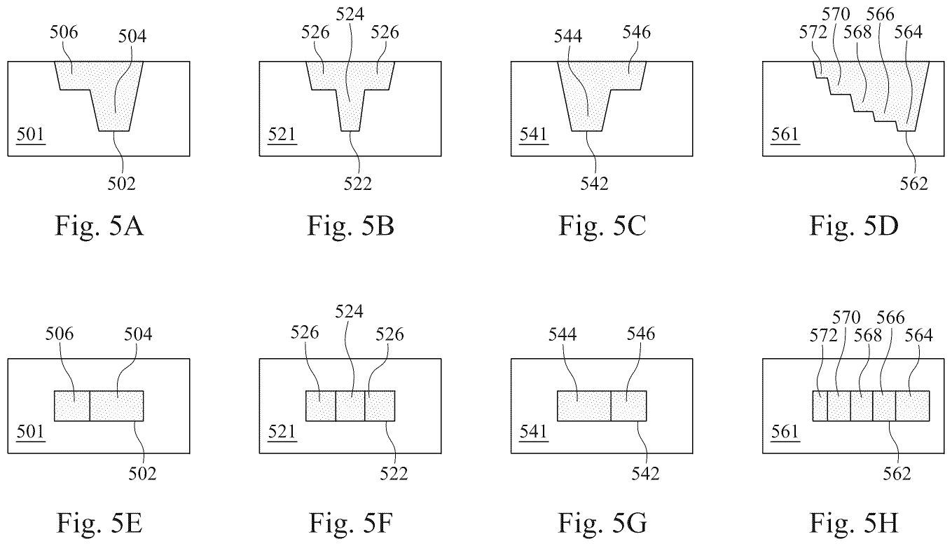

FIGS. 5A-5D are schematic cross-sectional views of example ladder STI configurations in a substrate and FIGS. 5E-5H are corresponding schematic top view of the example ladder STI configurations, according to various embodiments.

FIG. 5A illustrates an example substrate 501 with a 1L ladder STI structure 502 having a higher depth region 504 and a lower depth region 506. In this example, the lower depth region 506 of the 1L ladder STI structure 502 is on the left side of the 1L ladder STI structure 502 and the higher depth region 504 of the 1L ladder STI structure 502 is on the right side of the 1L ladder STI structure 502. FIG. 5E illustrates a top view of the substrate 501 with the 1L ladder STI structure 502 having the lower depth region 506 on the left side and the higher depth region 504 on the right side of the 1L ladder STI structure 502. This configuration may be considered a left 1L STI structure.

FIG. 5B illustrates an example substrate 521 with a 1L ladder STI structure 502 having a higher depth region 524 and lower depth regions 526. In this example, the lower depth region 526 of the 1L ladder STI structure 522 is on both the left side of the 1L ladder STI structure 522 and on the right side of the 1L ladder STI structure 522. The higher depth region 524 of the 1L ladder STI structure 522 is in the center of the 1L ladder STI structure 522. FIG. 5F illustrates a top view of the substrate 521 with the 1L ladder STI structure 522 having the lower depth regions 526 on both the left side and the right side of the 1L ladder STI structure 522 and the higher depth region 524 in the center of the 1L ladder STI structure 522. This configuration may be considered a middle 1L STI structure.

FIG. 5C illustrates an example substrate 541 with a 1L ladder STI structure 542 having a higher depth region 544 and a lower depth region 546. In this example, the lower depth region 546 of the 1L ladder STI structure 542 is on the right side of the 1L ladder STI structure 542 and the higher depth STI region 544 of the 1L ladder STI structure 542 is on the left side of the 1L ladder STI structure 542. FIG. 5G illustrates a top view of the substrate 541 with the 1L ladder STI structure 542 having the lower depth STI region 546 on the right side and the higher depth STI region 544 on the left side of the 1L ladder STI structure 542. This configuration may be considered a right 1L STI structure.

FIG. 5D illustrates an example substrate 561 with an xL ladder STI structure 562 having a plurality of regions of different depths. In this example x=4 and there are 5 (e.g., x+1) depth regions. The 5 depth regions include a first depth region 564 (e.g., the higher depth region), a second depth region 566, a third depth region 568, a fourth depth region 570, and a fifth depth region 572 (the lower depth region). In this example, the lower depth region 572 of the xL ladder STI structure 562 is on the left side of the xL ladder STI structure 562 and the higher depth region 564 of the xL ladder STI structure 562 is on the right side of the 1L ladder STI structure 562 with intermediate depth regions in depth order disposed between. FIG. 5H illustrates a top view of the substrate 561 with the xL ladder STI structure 562 having the lower depth region 572 on the left side, the higher depth region 564 on the right side of the xL ladder STI structure 562 with intermediate depth regions (second depth region 566, third depth region 568, fourth depth region 570) in depth order disposed between. This configuration may be considered a left-sided 4L STI structure. The multiple depth levels in this configuration may lead to faster device performance.

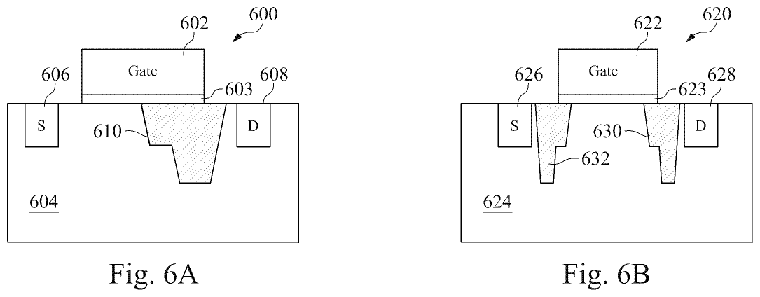

FIG. 6A, and 6B are schematic cross-sectional views of example devices (e.g., and LDMOS device or other device) that include ladder STI under a gate structure. FIG. 6A is a schematic cross-sectional view of an example device 600. The device 600 includes a gate structure 602 and gate oxide 603 over a substrate 604, a source feature 606 in the substrate 604, and a drain feature 608 in the substrate 604. The device 600 further includes a left 1L STI structure 610 in a channel region of the substrate 604 under the gate structure 602 on the drain side of the channel region. This configuration may be considered an asymmetric LDMOS device configuration.

FIG. 6B is a schematic cross-sectional view of an example device 620. The device 620 includes a gate structure 622 and gate oxide 623 over a substrate 624, a source feature 626 in the substrate 624, and a drain feature 628 in the substrate 624. The device 620 further includes a left 1L STI structure 630 in a channel region of the substrate 624 under the gate structure 622 on the drain side of the channel region, and a right 1L STI structure 632 in a channel region of the substrate 624 under the gate structure 622 on the source feature side of the channel region. This configuration may be considered a symmetric device configuration.

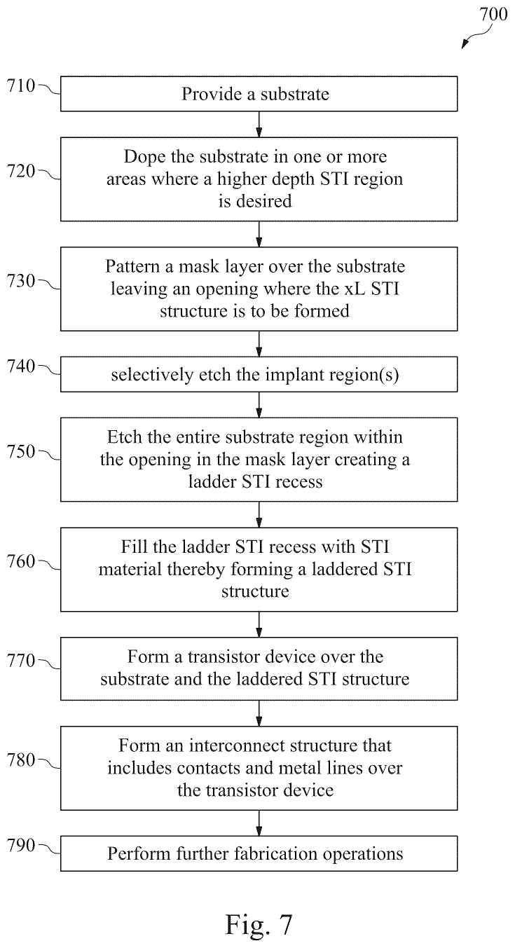

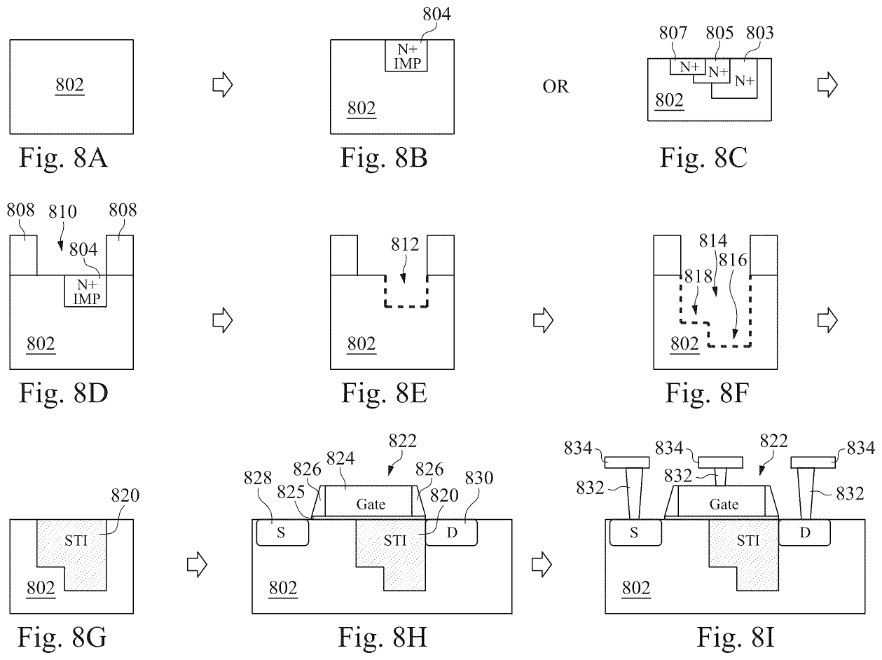

FIG. 7 is a flow diagram of an example method 700 for fabricating a semiconductor device having a ladder STI feature, according to some embodiments. For illustrative purposes, the operations illustrated in FIG. 7 will be described with reference to FIGS. 8A-8I, which show cross-sectional views of a semiconductor device at various stages of its fabrication process, according to some embodiments. Operations can be performed in a different order or not performed depending on specific applications. It should be noted that method 700 may not produce a complete semiconductor device. Accordingly, it is understood that additional processes can be provided before, during, and after method, and that some other processes may only be briefly described herein. In some figures, some reference numbers of components or features illustrated therein may be omitted to avoid obscuring other components or features; this is for ease of depicting the figures.

The method 700 is merely an example, and is not intended to limit the present disclosure beyond what is explicitly recited in the claims. Additional steps may be provided before, during, and after example method 700, and some of the steps described can be moved, replaced, or eliminated for additional embodiments of example method 700. Additional features may be added in the semiconductor device depicted in the figures and some of the features described below can be replaced, modified, or eliminated in other embodiments of the semiconductor device.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 700, including any descriptions given with reference to the Figures are merely exemplary and are not intended to be limiting beyond what is specifically recited in the claims that follow.

At block 710, the method 700 includes providing a semiconductor substrate. Referring to the example of FIG. 8A, in an embodiment of block 710, a semiconductor substrate 802 is provided. In various embodiments, the semiconductor substrate 802 is planar with a uniform thickness. Further, the semiconductor substrate 802 may be p-type, and can, for example, be a bulk silicon substrate or a SOI substrate.

At block 720, the method 700 includes doping the substrate in one or more areas where a higher depth STI region is desired. In embodiments wherein an xL STI structure with x =1 is desired, the substrate is doped at one depth. In embodiments wherein an xL STI structure with x>1 is desired, the substrate is doped at multiple depths. Each of the multiple depths will subsequently define a depth for a depth region in a subsequently formed xL STI structure. In various embodiments the depth of the doping is approximately equal to the difference in depth between a desired lower depth STI region and the desired higher depth STI region. In various embodiments, a p-type substrate is doped with an N+ implant. In various embodiments the N+ implant comprises Arsenic, Phosphorus, Stibium and/or other suitable materials.

Referring to the example of FIG. 8B, in an embodiment of block 720, the semiconductor substrate 802 is doped with an N+ implant 804 region. This allows for the formation of a 1L STI structure having 2 depth levels. Referring to the example of FIG. 8C, in another embodiment of block 720, the semiconductor substrate 802 is doped with a first N+ implant 803 region, a second N+ implant region 805, and a third N+ implant region 807. This allows for the formation of a 3L STI structure having 4 depth levels.

At block 730, the method 700 includes patterning a mask layer over the substrate leaving an opening where the xL STI structure is to be formed. Referring to the example of FIG. 8D, in an embodiment of block 730, a mask layer 808 is patterned over the substrate 802. The patterned mask layer 808 includes an opening 810 through which the substrate will subsequently be etched to form the xL STI structure.

At block 740, the method 700 includes selectively etching the implant region(s) within the opening leaving a recess. Referring to the example of FIG. 8E, in an embodiment of block 740, the implant region 804 has been selectively etched from the substrate 802 within the opening 810, using an appropriate etchant, leaving a recess 812. In various embodiments, when a plurality of implant regions (e.g., implant region 803, implant region 805, and implant region 807) are accessible via the opening 810, each of the plurality of implant regions are etched.

At block 750, the method 700 includes etching the entire substrate region within the opening in the mask layer creating a ladder STI recess. Referring to FIG. 8F, in an embodiment of block 750, the entire substrate region within the opening 810 is etched creating an STI recess area 814. The etching causes the previously etched areas of the substrate to be etched to a lower depth than the previously unetched areas of the substrate within the opening 810. This results in the STI recess area 814 having a first area 816 at a first depth and a second area 818 at a second depth. In various embodiments, etching the substrate region within the opening in the mask layer includes etching the substrate region using a dry etch technique.

At block 760, the method 700 includes filling the STI recess area with STI material thereby forming a ladder STI structure. Referring to FIG. 8G, in an embodiment of block 760, the STI recess area 814 is filled with STI material thereby forming a ladder STI structure 820.

At block 770, the method 700 includes forming a transistor device over the substrate and the ladder STI structure. Referring to FIG. 8H, in an embodiment of block 770, an LDMOS device 822 is formed over the substrate 802 and the ladder STI structure 820. The LDMOS device 822 includes a gate structure 824, gate oxide 825, and gate spacers 826 over the substrate 802. The LDMOS device 822 further includes a source feature 828 in the substrate 802 and a drain feature 830 in the substrate 802. The ladder STI structure 820 is formed in drain side of the channel region of the substrate 802.

At block 780, the method 700 includes forming an interconnect structure that includes contacts and metal lines over the transistor device to connect the transistor device to other components in a semiconductor device. Referring to FIG. 8I, in an embodiment of block 780, the LDMOS device 822 is provided with contacts 832 and metal lines 834 to connect the LDMOS device 822 to other components (not shown) in a semiconductor device.

At block 790, the method 700 includes performing further fabrication operations to complete the semiconductor device.

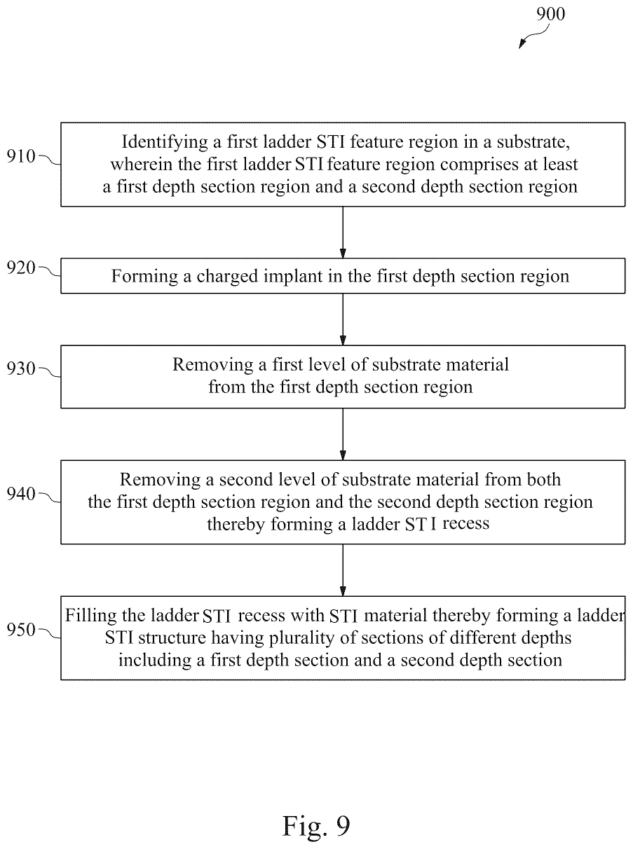

FIG. 9 is a flow diagram of an example method 900 for fabricating a semiconductor device having a ladder STI feature, according to some embodiments. For illustrative purposes, the operations illustrated in FIG. 9 will be described with reference to FIGS. 8A-8I, which show cross-sectional views of a semiconductor device at various stages of its fabrication process, according to some embodiments. Operations can be performed in a different order or not performed depending on specific applications. It should be noted that method 900 may not produce a complete semiconductor device. Accordingly, it is understood that additional processes can be provided before, during, and after method, and that some other processes may only be briefly described herein. In some figures, some reference numbers of components or features illustrated therein may be omitted to avoid obscuring other components or features; this is for ease of depicting the figures.

The method 900 is merely an example, and is not intended to limit the present disclosure beyond what is explicitly recited in the claims. Additional steps may be provided before, during, and after example method 900, and some of the steps described can be moved, replaced, or eliminated for additional embodiments of example method 900. Additional features may be added in the semiconductor device depicted in the figures and some of the features described below can be replaced, modified, or eliminated in other embodiments of the semiconductor device.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 900, including any descriptions given with reference to the Figures are merely exemplary and are not intended to be limiting beyond what is specifically recited in the claims that follow.

At block 910, the method 900 includes identifying a first ladder STI feature region (e.g., the region where ladder STI structure 820 will be formed) in a substrate, wherein the first ladder STI feature region comprises at least a first depth section region (e.g., first area 816) and a second depth section region (e.g., second area 818).

At block 920, the method 900 includes forming a charged implant in the first depth section region. In various embodiments, forming the charged implant in the first depth section comprises doping the first depth section region. In various embodiments, the charged implant comprises a negatively charged (N+) implant. Referring to FIG. 8B, in an embodiment of block 920, a charged implant is formed in implant region 804 (e.g., the first depth section region).

At block 930, the method 900 includes removing a first level of substrate material from the first depth section region. In various embodiments, removing the first level of substrate material from the first depth section region comprises selectively etching the substrate with an etchant that is selective to the charged implant.

At block 940, the method 900 includes removing a second level of substrate material from both the first depth section region and the second depth section region thereby forming a ladder STI recess. In various embodiments, removing the second level of substrate material from both the first depth section region and the second depth section region comprises performing dry etching operations on the first ladder STI feature region.

At block 950, the method 900 includes filling the ladder STI recess with STI material thereby forming a ladder STI structure having plurality of sections of different depths including a first depth section and a second depth section. In various embodiments, filling the ladder STI recess with STI material comprises depositing the STI material using ALD, CVD, or other suitable technique.

In various embodiments, the method further comprises forming a transistor device over the substrate and the ladder STI structure.

In various embodiments, the novel ladder STI structure and method disclosed herein can provide sufficient isolation for HV application and higher operation speed. While the foregoing ladder STI features were described with reference to their use with LDMOS devices, the ladder STI features are not limited to such uses. Ladder STI features may be used in other applications such as CMOS transistors that requires a higher operation voltage (e.g., driver IC, power management integrated circuit (PMIC), sensors).

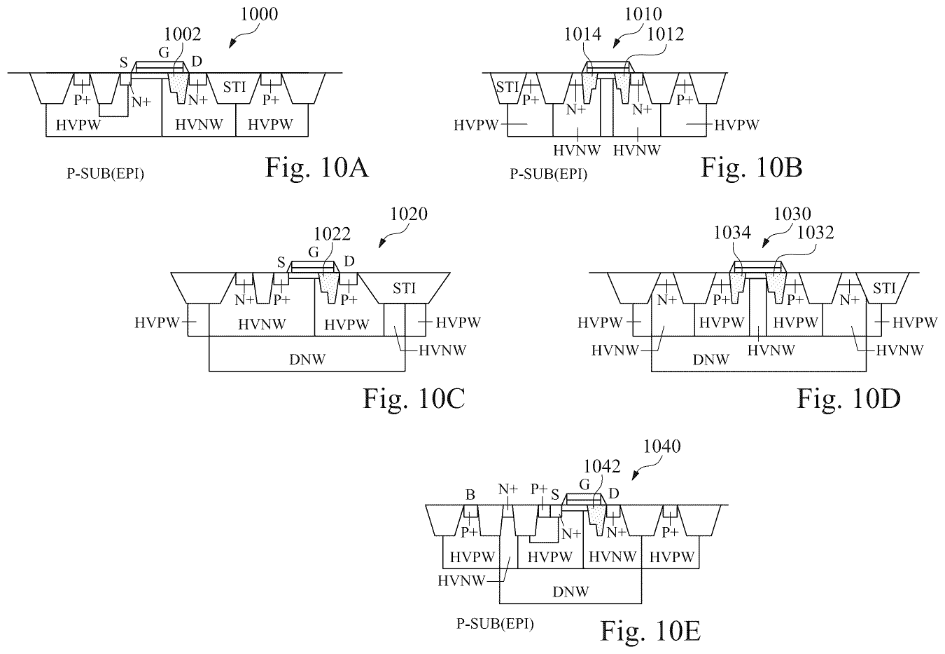

FIGS. 10A-10E are schematic cross-sectional views of example LDMOS devices that include a ladder STI feature, according to some embodiments. FIG. 10A depicts an example HV Asymmetric NMOS device 1000 that includes a ladder STI feature 1002. FIG. 10B depicts an example HV Symmetric NMOS device 1010 that includes a first ladder STI feature 1012 and a second ladder STI feature 1014. FIG. 10C depicts an example HV Asymmetric PMOS device 1020 that includes a ladder STI feature 1022. FIG. 10D depicts an example HV Symmetric PMOS device 1030 that includes a first ladder STI feature 1032 and a second ladder STI feature 1034. FIG. 10E depicts an example HV Isolated NMOS device 1040 that includes a ladder STI feature 1042. The various features and techniques described herein can be implemented in any of these devices and others.

In some aspects, the techniques described herein relate to a semiconductor structure, including: a source feature and a drain feature disposed in a substrate; a gate structure disposed above the substrate and between the source feature and the drain feature; and a first ladder shallow trench isolation (STI) feature disposed in the substrate at least partially under the gate structure in a channel region between the source feature and the drain feature, the first ladder STI feature including a plurality of sections of different depths including a first depth section and a second depth section.

In some aspects, the techniques described herein relate to a semiconductor structure, wherein the source feature includes a first doped region and the drain feature includes a second doped region, and wherein the first doped region and the second doped region are both of a first polarity type.

In some aspects, the techniques described herein relate to a semiconductor structure, wherein the first polarity type is a positive polarity.

In some aspects, the techniques described herein relate to a semiconductor structure, wherein the first polarity type is a negative polarity.

In some aspects, the techniques described herein relate to a semiconductor structure, wherein the channel region has a drain side that spans between the second doped region and an area in the substrate that is below a middle position of the gate structure in a lateral direction, and the first ladder STI feature is disposed on the drain side of the channel region.

In some aspects, the techniques described herein relate to a semiconductor structure, further including a single depth STI feature disposed in the substrate at least partially under a second gate structure in a second channel region between a second source feature and a second drain feature, wherein: the single depth STI feature has a STI depth and a STI width; the first depth section has a first depth that is equal to the STI depth; the second depth section has a second depth that is less than the STI depth; and the first ladder STI feature has a width that is equal to the STI width.

In some aspects, the techniques described herein relate to a semiconductor structure, further including a single depth STI feature disposed in the substrate at least partially under a second gate structure in a second channel region between a second source feature and a second drain feature, wherein: the single depth STI feature has a STI depth and a STI width; the first depth section has a first depth that is greater than the STI depth; the second depth section has a second depth that is less than the STI depth; and the first ladder STI feature has a width that is greater than the STI width.

In some aspects, the techniques described herein relate to a semiconductor structure, further including a single depth STI feature disposed in the substrate at least partially under a second gate structure in a second channel region between a second source feature and a second drain feature, wherein: the single depth STI feature has a STI depth and a STI width; the first depth section has a first depth that is less than the STI depth; the second depth section has a second depth that is less than the STI depth; and the first ladder STI feature has a width that is greater than the STI width.

In some aspects, the techniques described herein relate to a semiconductor structure, wherein: the substrate includes a high voltage n-well (HVNW) and a high voltage p-well (HVPW); the source feature is disposed in the HVNW; and both the drain feature and the first ladder STI feature are disposed in the HVPW.

In some aspects, the techniques described herein relate to a semiconductor structure, wherein: the substrate includes a high voltage n-well (HVNW) and a high voltage p-well (HVPW); the source feature is disposed in the HVPW; and both the drain feature and the first ladder STI feature are disposed in the HVNW.

In some aspects, the techniques described herein relate to a semiconductor structure, further including a second ladder STI feature disposed in the substrate at least partially under the gate structure in the channel region between the source feature and the drain feature, the second ladder STI feature including a plurality of sections of different depths equal to the plurality of sections of different depths in the first ladder STI feature, wherein: the channel region has a drain side that spans between the second doped region and an area in the substrate that is below a middle position of the gate structure in a lateral direction; the channel region has a source side that spans between the first doped region and the area in the substrate that is below the middle position of the gate structure in the lateral direction; the first ladder STI feature is disposed on the drain side of the channel region; and the second ladder STI feature is disposed on the source side of the channel region.

In some aspects, the techniques described herein relate to a semiconductor structure, wherein: the substrate includes a first high voltage n-well (HVNW), a second HVNW, a first high voltage p-well (HVPW), and a second HVPW; the drain feature and the first ladder STI feature are disposed in the first HVNW; and the source feature and the second ladder STI feature are disposed in the second HVNW.

In some aspects, the techniques described herein relate to a semiconductor structure, wherein: the substrate includes a first high voltage n-well (HVNW), a second HVNW, a first high voltage p-well (HVPW), and a second HVPW; the drain feature and the first ladder STI feature are disposed in the first HVPW; and the source feature and the second ladder STI feature are disposed in the second HVPW.

In some aspects, the techniques described herein relate to a semiconductor structure, wherein the first depth section has a first depth, the second depth section has a second depth, the first depth is greater than the second depth, and the first depth section is right of the second depth section.

In some aspects, the techniques described herein relate to a semiconductor structure, wherein the first depth section has a first depth, the second depth section has a second depth, the first depth is greater than the second depth, and the first depth section is left of the second depth section.

In some aspects, the techniques described herein relate to a semiconductor structure, wherein the ratio of the first depth to the second depth is from about 1.2 to 1 to about 3 to 1.

In some aspects, the techniques described herein relate to a semiconductor structure, further including a third depth section, wherein the first depth section has a first depth, the second depth section has a second depth, the third depth section has a depth that is equal to the second depth, the first depth is greater than the second depth, and the first depth section is disposed between the second depth section and the third depth section.

In some aspects, the techniques described herein relate to a semiconductor structure, further including a third depth section, wherein the first depth section has a first depth, the second depth section has a second depth, the third depth section has a third depth, the first depth is greater than the second depth, the second depth is greater than the third depth, the first depth section is disposed left of the second depth section, and the second depth section is disposed left of the third depth section.

In some aspects, the techniques described herein relate to a semiconductor structure, further including a third depth section, wherein the first depth section has a first depth, the second depth section has a second depth, the third depth section has a third depth, the first depth is greater than the second depth, the second depth is greater than the third depth, the first depth section is disposed right of the second depth section, and the second depth section is disposed right of the third depth section.

In some aspects, the techniques described herein relate to a semiconductor structure, wherein the first ladder STI feature further comprises a top surface, a curved first wall between the top surface and a curved first bottom surface, a curved second wall between the first bottom surface and a curved second bottom surface, and a third curved wall between the second bottom surface and the top surface.

In some aspects, the techniques described herein relate to a fabrication method, including: identifying a first ladder STI feature region in a substrate, wherein the first ladder STI feature region includes at least a first depth section region and a second depth section region; forming a charged implant in the first depth section region; removing a first level of substrate material from the first depth section region; removing a second level of substrate material from both the first depth section region and the second depth section region thereby forming a ladder STI recess; and filling the ladder STI recess with STI material thereby forming a ladder STI structure having plurality of sections of different depths including a first depth section and a second depth section.

In some aspects, the techniques described herein relate to a fabrication method, wherein forming the charged implant in the first depth section includes doping the first depth section region.

In some aspects, the techniques described herein relate to a fabrication method, wherein the charged implant includes a negatively charged (N+) implant.

In some aspects, the techniques described herein relate to a fabrication method, wherein removing the first level of substrate material from the first depth section region includes selectively etching the substrate with an etchant that is selective to the charged implant.

In some aspects, the techniques described herein relate to a fabrication method, wherein removing the second level of substrate material from both the first depth section region and the second depth section region includes performing dry etching operations on the first ladder STI feature region.

In some aspects, the techniques described herein relate to a fabrication method, further including forming a transistor device over the substrate and the ladder STI structure.

In some aspects, the techniques described herein relate to a fabrication method, wherein the ladder STI structure includes a first outer angle between a top surface of the ladder STI structure and a first wall of the ladder STI structure, a second outer angle between a bottom surface of the second depth section and a third wall of the ladder STI structure, and a third outer angle between the top surface of the ladder STI structure and a second wall of the ladder STI structure, and wherein a magnitude of the first outer angle is equal to a magnitude of the third outer angle and a magnitude of the second outer angle is less than the magnitude of the first outer angle and the magnitude of the third outer angle.

In some aspects, the techniques described herein relate to a fabrication method, wherein the ladder STI structure includes a first inner angle between a first wall of the ladder STI structure and a bottom surface of the second depth section of the ladder STI structure, a second inner angle between a bottom surface of the first depth section and a third wall of the ladder STI structure, and a third inner angle between the bottom surface of the first depth section and a second wall of the ladder STI structure, and wherein a magnitude of the second inner angle is equal to a magnitude of the third inner angle and a magnitude of the first inner angle is greater than the magnitude of the second inner angle and the magnitude of the third inner angle.

In some aspects, the techniques described herein relate to a semiconductor structure, including: a source feature including a first doped region and a drain feature including a second doped region disposed in a substrate; a channel region disposed in the substrate between the source feature and the drain feature; a gate structure disposed above the channel region, wherein the channel region has a drain side that spans between the second doped region and an area in the substrate that is below a middle position of the gate structure in a lateral direction; and a ladder shallow trench isolation (STI) feature disposed on the drain side of the channel region, the first ladder STI feature including a plurality of sections of different depths including a first depth section and a second depth section.

In some aspects, the techniques described herein relate to a semiconductor structure, including a laterally-diffused metal-oxide semiconductor (LDMOS) device.

In some aspects, the techniques described herein relate to a semiconductor structure, wherein: the substrate includes a well region with a first type of conductivity and a well region with a second type of conductivity; the source feature is disposed in the well region with the first type of conductivity; and both the drain feature and the first ladder STI feature are disposed in the well region with the second type of conductivity.

In some aspects, the techniques described herein relate to a semiconductor structure, further including: a first outer angle between a top surface of the ladder STI structure and a first wall of the ladder STI structure, a second outer angle between a bottom surface of the second depth section and a third wall of the ladder STI structure, and a third outer angle between the top surface of the ladder STI structure and a second wall of the ladder STI structure, and wherein a magnitude of the first outer angle is equal to a magnitude of the third outer angle and a magnitude of the second outer angle is less than the magnitude of the first outer angle and the magnitude of the third outer angle; a first inner angle between the first wall of the ladder STI structure and the bottom surface of the second depth section of the ladder STI structure, a second inner angle between the bottom surface of the first depth section and the third wall of the ladder STI structure, and a third inner angle between the bottom surface of the first depth section and the second wall of the ladder STI structure, and wherein a magnitude of the second inner angle is equal to a magnitude of the third inner angle and a magnitude of the first inner angle is greater than the magnitude of the second inner angle and the magnitude of the third inner angle; and each of the first inner angle, second inner angle, third inner angle, first outer angle, second outer angle, and third outer angle has a magnitude greater than (>) 90° and less than (<) 180°.

In some aspects, the techniques described herein relate to a semiconductor structure, further including a second ladder STI feature disposed in the substrate at least partially under the gate structure in the channel region between the source feature and the drain feature, the second ladder STI feature including a plurality of sections of different depths equal to the plurality of sections of different depths in the first ladder STI feature, wherein: the channel region has a source side that spans between the first doped region and the area in the substrate that is below the middle position of the gate structure in the lateral direction; and the second ladder STI feature is disposed on the source side of the channel region.

In some aspects, the techniques described herein relate to a semiconductor structure, wherein: the substrate includes a first well region with a first type of conductivity, a second well region with the first type of conductivity, a first well region with a second type of conductivity, and a second well region with the second type of conductivity; the drain feature and the first ladder STI feature are disposed in the first well region with the first type of conductivity; and the source feature and the second ladder STI feature are disposed in the second well region with the second type of conductivity.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure, comprising:
a source feature and a drain feature disposed in a substrate;
a gate structure disposed above the substrate and between the source feature and the drain feature; and
a first ladder shallow trench isolation (STI) feature disposed in the substrate at least partially under the gate structure in a channel region between the source feature and the drain feature, the first ladder STI feature comprising a plurality of sections of different depths including a first depth section and a second depth section.

2. The semiconductor structure of claim 1, wherein the channel region has a drain side that spans between a doped region of the drain feature and an area in the substrate that is below a middle position of the gate structure in a lateral direction, and the first ladder STI feature is disposed on the drain side of the channel region.

3. The semiconductor structure of claim 1, wherein the first depth section has a first depth, the second depth section has a second depth, and the first depth is greater than the second depth.

4. The semiconductor structure of claim 3, wherein a ratio of the first depth to the second depth is from about 1.2 to 1 to about 3 to 1.

5. The semiconductor structure of claim 1, further comprising a third depth section, wherein the first depth section has a first depth, the second depth section has a second depth, the third depth section has a depth that is equal to the second depth, the first depth is greater than the second depth, and the first depth section is disposed between the second depth section and the third depth section.

6. The semiconductor structure of claim 1, further comprising a third depth section, wherein the first depth section has a first depth, the second depth section has a second depth, the third depth section has a third depth, the first depth is greater than the second depth, the second depth is greater than the third depth, the first depth section is disposed left of the second depth section, and the second depth section is disposed left of the third depth section.

7. The semiconductor structure of claim 1, wherein the first ladder STI feature further comprises a top surface, a curved first wall between the top surface and a curved first bottom surface, a curved second wall between the first bottom surface and a curved second bottom surface, and a third curved wall between the second bottom surface and the top surface.

8. A fabrication method, comprising:
identifying a first ladder STI feature region in a substrate, wherein the first ladder STI feature region comprises at least a first depth section region and a second depth section region;
forming a charged implant in the first depth section region;
removing a first level of substrate material from the first depth section region;
removing a second level of substrate material from both the first depth section region and the second depth section region thereby forming a ladder STI recess; and
filling the ladder STI recess with STI material thereby forming a ladder STI structure having plurality of sections of different depths including a first depth section and a second depth section.

9. The fabrication method of claim 8, wherein forming the charged implant in the first depth section comprises doping the first depth section region with a negatively charged (N+) implant.

10. The fabrication method of claim 8, wherein removing the first level of substrate material from the first depth section region comprises selectively etching the substrate with an etchant that is selective to the charged implant.

11. The fabrication method of claim 8, wherein removing the second level of substrate material from both the first depth section region and the second depth section region comprises performing dry etching operations on the first ladder STI feature region.

12. The fabrication method of claim 8, wherein the ladder STI structure comprises a first outer angle between a top surface of the ladder STI structure and a first wall of the ladder STI structure, a second outer angle between a bottom surface of the second depth section and a third wall of the ladder STI structure, and a third outer angle between the top surface of the ladder STI structure and a second wall of the ladder STI structure, and wherein a magnitude of the first outer angle is equal to a magnitude of the third outer angle and a magnitude of the second outer angle is less than the magnitude of the first outer angle and the magnitude of the third outer angle.

13. The fabrication method of claim 8, wherein the ladder STI structure comprises a first inner angle between a first wall of the ladder STI structure and a bottom surface of the second depth section of the ladder STI structure, a second inner angle between a bottom surface of the first depth section and a third wall of the ladder STI structure, and a third inner angle between the bottom surface of the first depth section and a second wall of the ladder STI structure, and wherein a magnitude of the second inner angle is equal to a magnitude of the third inner angle and a magnitude of the first inner angle is greater than the magnitude of the second inner angle and the magnitude of the third inner angle.

14. A semiconductor structure, comprising:
a source feature comprising a first doped region and a drain feature comprising a second doped region disposed in a substrate;
a channel region disposed in the substrate between the source feature and the drain feature;
a gate structure disposed above the channel region, wherein the channel region has a drain side that spans between the second doped region and an area in the substrate that is below a middle position of the gate structure in a lateral direction; and
a first ladder shallow trench isolation (STI) feature disposed on the drain side of the channel region, the first ladder STI feature comprising a plurality of sections of different depths including a first depth section and a second depth section.

15. The semiconductor structure of claim 14, further comprising a single depth STI feature disposed in the substrate at least partially under a second gate structure in a second channel region between a second source feature and a second drain feature, wherein:
the single depth STI feature has a STI depth and a STI width;
the first depth section has a first depth that is equal to the STI depth;
the second depth section has a second depth that is less than the STI depth; and
the first ladder STI feature has a width that is equal to the STI width.

16. The semiconductor structure of claim 14, further comprising a single depth STI feature disposed in the substrate at least partially under a second gate structure in a second channel region between a second source feature and a second drain feature, wherein:
the single depth STI feature has a STI depth and a STI width;
the first depth section has a first depth that is greater than the STI depth;
the second depth section has a second depth that is less than the STI depth; and
the first ladder STI feature has a width that is greater than the STI width.

17. The semiconductor structure of claim 14, further comprising a single depth STI feature disposed in the substrate at least partially under a second gate structure in a second channel region between a second source feature and a second drain feature, wherein:
the single depth STI feature has a STI depth and a STI width;
the first depth section has a first depth that is less than the STI depth;
the second depth section has a second depth that is less than the STI depth; and
the first ladder STI feature has a width that is greater than the STI width.

18. The semiconductor structure of claim 14, wherein:
the substrate comprises a well region with a first type of conductivity and a well region with a second type of conductivity;
the source feature is disposed in the well region with the first type of conductivity; and
both the drain feature and the first ladder STI feature are disposed in the well region with the second type of conductivity.

19. The semiconductor structure of claim 14, further comprising:
a first outer angle between a top surface of the first ladder STI feature and a first wall of the first ladder STI feature, a second outer angle between a bottom surface of the second depth section and a third wall of the first ladder STI feature, and a third outer angle between the top surface of the first ladder STI feature and a second wall of the first ladder STI feature, and wherein a magnitude of the first outer angle is equal to a magnitude of the third outer angle and a magnitude of the second outer angle is less than the magnitude of the first outer angle and the magnitude of the third outer angle;
a first inner angle between the first wall of the first ladder STI feature and the bottom surface of the second depth section of the first ladder STI feature, a second inner angle between the bottom surface of the first depth section and the third wall of the first ladder STI feature, and a third inner angle between the bottom surface of the first depth section and the second wall of the first ladder STI feature, and wherein a magnitude of the second inner angle is equal to a magnitude of the third inner angle and a magnitude of the first inner angle is greater than the magnitude of the second inner angle and the magnitude of the third inner angle; and
each of the first inner angle, second inner angle, third inner angle, first outer angle, second outer angle, and third outer angle having a magnitude greater than (>) 90° and less than (<) 180°.

20. The semiconductor structure of claim 14, further comprising a second ladder STI feature disposed in the substrate at least partially under the gate structure in the channel region between the source feature and the drain feature, the second ladder STI feature comprising a plurality of sections of different depths equal to the plurality of sections of different depths in the first ladder STI feature, wherein:
the channel region has a source side that spans between the first doped region and the area in the substrate that is below the middle position of the gate structure in the lateral direction; and
the second ladder STI feature is disposed on the source side of the channel region.
